(19) United States
(12) Patent Application Publication
(10) Pub. No.: US 2015/0206773 A1
(43) Pub. Date: Jul. 23, 2015

(54) SUBSTRATE PROCESSING METHOD AND APPARATUS THEREFOR

(71) Applicant: KABUSHIKI KAISHA TOSHIBA, Tokyo (JP)

(72) Inventors: Hidekazu HAYASHI, Yokkaichi-Shi (JP); Yohei Sato, Yokkaichi-Shi (JP); Hisashi Okuchi, Yokkaichi-Shi (JP); Hiroshi Tomita, Yokohama-Shi (JP)

(21) Appl. No.: 14/200,672

(22) Filed: Mar. 7, 2014

(30) Foreign Application Priority Data
Jan. 17, 2014 (JP) 2014-007134

(51) Int. Cl. H01L 21/67; B08B 3/08; B08B 3/10; H01L 21/02

(52) U.S. Cl. CPC H01L 21/67034; H01L 21/02101; H01L 21/6704; B08B 3/08; B08B 3/10

(57) ABSTRACT

In accordance with a substrate processing method according to the present embodiment, ultrapure water is supplied to a surface of a substrate. A fluoroalcohol-containing solvent is supplied to the surface of the substrate, to which the ultrapure water has been attached. A first solvent, which has solubility in the fluoroalcohol-containing solvent and is different from the fluoroalcohol-containing solvent, is supplied to the surface of the substrate, to which the fluoroalcohol-containing solvent has been attached. The substrate, to which the first solvent has been attached, is introduced into a chamber, the first solvent on the surface of the substrate is substituted with a supercritical fluid, and then, a pressure within the chamber is reduced and the supercritical fluid is changed into gas. The substrate is brought out from the chamber.

### CROSS-REFERENCE TO RELATED APPLICATION

This application is based upon and claims the benefit of priority from Japanese Patent Application No 2014-007134, filed Jan. 17, 2014; the entire contents of which are incorporated herein by reference.

### FIELD

Embodiments described herein relate to a substrate processing method and an apparatus therefor.

### BACKGROUND

In a semiconductor device manufacturing process in which a laminated structure of an integrated circuit is formed on a surface of a substrate, such as a semiconductor wafer (referred to as “wafer” hereinafter), a liquid processing process of removing a fine dust or a natural oxide film on a substrate surface by utilizing a liquid, such as a cleaning liquid, is provided.

With high integration of the semiconductor device, a phenomenon called a so-called pattern collapse has become a problem in such a liquid processing process. The pattern collapse is a phenomenon in which, upon drying a liquid attached to pattern surfaces on a substrate, since the liquid unevenly vaporizes on adjacent pattern surfaces on the substrate, liquid level heights existing between the patterns become different, and the patterns are collapsed by a capillary force caused by surface tension of the liquid.

A method of using a supercritical fluid has been known as the method of drying a liquid attached to a substrate surface while suppressing occurrence of such a pattern collapse. The supercritical fluid has small viscosity and high liquid extraction ability as compared to a liquid. Accordingly, by bringing the supercritical fluid into contact with the substrate surface wet with the liquid, the liquid on the substrate surface is extracted into the supercritical fluid, and the liquid can be easily substituted with the supercritical fluid. Since an interface between a gas phase and a liquid phase does not exist in a supercritical state, when the liquid on the substrate surface is substituted with the supercritical fluid, and then a pressure is reduced, the supercritical fluid covering the substrate surface is immediately changed to gas. With this construction, the liquid on the substrate surface can be removed and dried without being affected by surface tension.

A supercritical drying method using a fluorine-containing organic solvent, such as fluoroalcohol, hydro fluoro ether (FIFE), chlorofluorocarbon (CFC), hydrofluorocarbon (HFC), and perfluoro carbon (PFC), has been known as a conventional technique. In this conventional technique, after a substrate surface is cleaned with a cleaning liquid, pure water and alcohol are sequentially supplied to the substrate surface. A fluorine-containing organic solvent is supplied to the substrate surface and substituted with the alcohol. The substrate is conveyed into a chamber with the fluorine-containing organic solvent filled up on the substrate surface and without being dried. A phase of the fluorine-containing organic solvent is changed to a supercritical state by heating.

At this time, for the fluorine-containing organic solvent filled up on the substrate surface, it is preferable to use a high boiling point solvent, which does not volatilize when conveying the substrate to the chamber. However, in general, the high boiling point solvent has a high critical temperature. Accordingly, when the phase of the fluorine-containing organic solvent supplied to the chamber is changed to the supercritical state under a high temperature and high pressure atmosphere, thermal decomposition occurs, and fluorine atoms are generated. There is a problem in that the substrate is damaged by the fluorine atoms.

### BRIEF DESCRIPTION OF THE DRAWINGS

FIG. 1 is a diagram illustrating an example of a liquid processing unit according to a first embodiment;

FIG. 2 is a diagram illustrating an example of a supercritical drying processing unit according to the first embodiment;

FIG. 3 is a process flow chart illustrating an example of a substrate processing method according to the first embodiment; and

FIG. 4 is a process flow chart illustrating an example of a substrate processing method according to a second embodiment.

### DETAILED DESCRIPTION

Embodiments will now be explained with reference to the accompanying drawings. The present invention is not limited to the embodiments.

A problem to be solved by the present invention is to provide a substrate processing method and an apparatus therefor capable of performing a supercritical drying process without causing failures, such as a pattern collapse.

In accordance with a substrate processing method according to the present embodiment, ultrapure water is supplied to a surface of a substrate. A fluoroalcohol-containing solvent is supplied to the surface of the substrate, to which the ultrapure water has been attached. A first solvent, which has solubility in the fluoroalcohol-containing solvent and is different from the fluoroalcohol-containing solvent, is supplied to the surface of the substrate, to which the fluoroalcohol-containing solvent has been attached. The substrate, to which the first solvent has been attached, is introduced into a chamber, the first solvent on the surface of the substrate is substituted with a supercritical fluid, and then, a pressure within the chamber is reduced and the supercritical fluid is changed into gas. The substrate is brought out from the chamber.

### First Embodiment

A substrate processing method and apparatus therefor according to a first embodiment of the present invention will be described below with reference to the drawings. The substrate processing apparatus according to the present embodiment includes a liquid processing unit 10, which performs liquid processing on a wafer W serving as a substrate with various processing liquids, and a supercritical drying processing unit (supercritical drying unit) 20, which performs extraction and substitution by bringing a liquid attached to a surface of the processed wafer W into contact with a supercritical fluid.

### (Liquid Processing Unit)

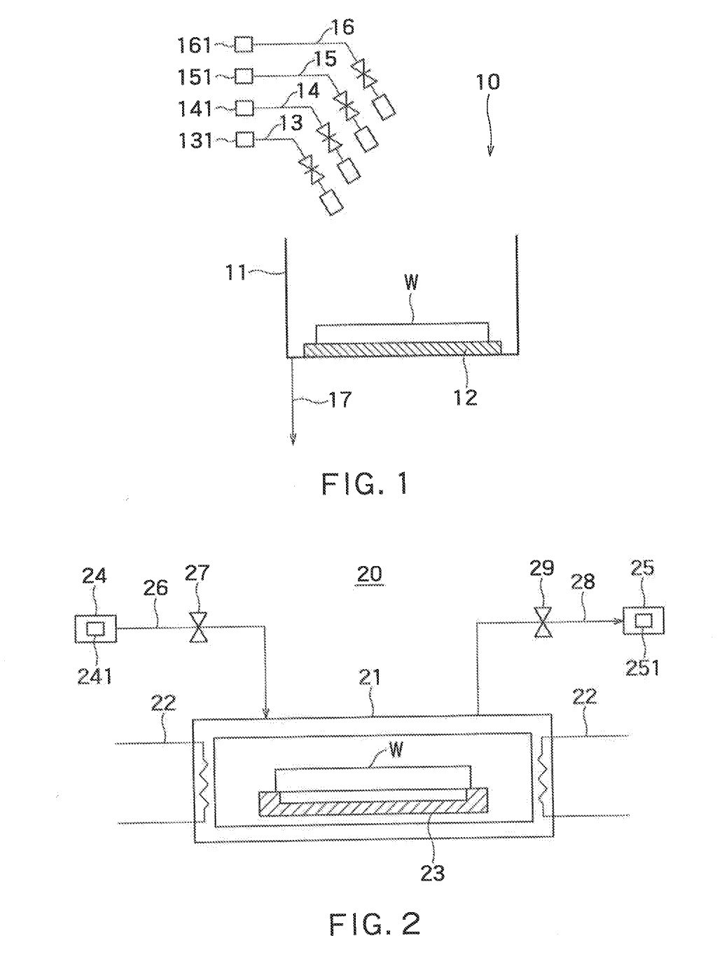

FIG. 1 is a diagram illustrating an example of a liquid processing unit 10. The liquid processing unit 10 is, for example, configured as a sheet type liquid processing unit, which cleans the wafers W one by one by spin cleaning, and a batch type liquid processing unit, which simultaneously performs liquid processing of the plurality of wafers W. The liquid processing unit 10 includes a liquid processing chamber 11, a wafer holding section 12, a cleaning liquid supply section 13, an ultrapure water supply section 14, a first solvent supply section 15, and an intermediate solvent supply section 16.

The liquid processing chamber 11 forms a processing space where the liquid processing by the liquid processing unit 10 is performed. A liquid discharge pipe 17 for discharging a cleaning liquid or the like used for the liquid processing is provided at a bottom portion of the liquid processing chamber 11.

The wafer holding section 12 is disposed within the liquid processing chamber 11, and holds the wafer W substantially horizontally. As the wafer holding section 12 rotates in a state of holding the wafer W, the liquid processing unit 10 is capable of spin cleaning the wafer W.

The cleaning liquid supply section 13 is provided in such a manner that the cleaning liquid, which cleans a surface of the wafer W, can be supplied to the surface of the wafer W held by the wafer holding section 12. The cleaning liquid supply section 13 includes, for example, a storage 131, which stores the cleaning liquid, and a nozzle, which supplies the cleaning liquid stored in the storage to the surface of the wafer W. As the cleaning liquid, for example, an alkaline cleaning liquid SC1 (mixed liquid of ammonia and hydrogen peroxide solution), an acidic cleaning liquid DHF (diluted hydrofluoric acid), or the like is supplied.

The ultrapure water supply section 14 is provided in such a manner that ultrapure water, which rinses the surface of the wafer W, can be supplied to the surface of the wafer W held by the wafer holding section 12. The ultrapure water supply section 14 includes, for example, a storage 141, which stores the ultrapure water, and a nozzle, which supplies the ultrapure water stored in the storage to the surface of the wafer W. As the ultrapure water, for example, a DIW (deionized water) or the like is supplied.

The first solvent supply section (first solvent supply section) 15 is provided in such a manner that a first solvent, which prevents drying of the surface of the wafer W, can be supplied to the surface of the wafer W held by the wafer holding section 12. The first solvent supply section 15 includes, for example, a storage 151, which stores the first solvent, and a nozzle, which supplies the first solvent stored in the storage to the surface of the wafer W. As the first solvent, for example, a fluorine-containing organic solvent is used. The solvent used as the first solvent is selected based on a relationship to a second solvent, to be described below. Details of the first solvent will be described below.

The intermediate solvent supply section (fluoroalcohol-containing solvent supply section) 16 is provided in such a manner that an intermediate solvent can be supplied to the surface of the wafer W held by the wafer holding section 12. The intermediate solvent supply section 16 includes, for example, a storage 161, which stores the intermediate solvent, and a nozzle, which supplies the intermediate solvent stored in the storage to the surface of the wafer W. In the liquid processing, after the surface of the wafer W is rinsed by supplying the ultrapure water to the surface of the wafer W, the intermediate solvent is supplied to the surface of the wafer W, and the ultrapure water attached to the surface of the wafer W is substituted with the intermediate solvent. Further, the first solvent is supplied to the surface of the wafer W, and the intermediate solvent is substituted with the first solvent. In other words, the intermediate solvent is a solvent used intermediately for substituting the ultrapure water attached to the surface of the wafer W with the first solvent. Accordingly, a solvent having solubility in the ultrapure water and having solubility in the first solvent is used as the intermediate solvent. Details of the intermediate solvent will be described below.

It should be noted that processing liquid supply paths connected to the aforementioned cleaning liquid supply section 13, the ultrapure water supply section 14, the first solvent supply section 15, and the intermediate solvent supply section 16 may be formed inside the wafer holding section 12. With this configuration, the various processing liquids, such as the cleaning liquid, the ultrapure water, the first solvent, and the intermediate solvent, are supplied via the processing liquid supply paths, and the liquid processing of a rear surface of the wafer W can be realized.

### (Supercritical Drying Processing Unit)

FIG. 2 is a diagram illustrating an example of the supercritical drying processing unit 20. The supercritical drying processing unit 20 performs drying processing with a supercritical fluid to the wafer W, which has been subjected to the liquid processing by the liquid processing unit 10. The supercritical drying processing unit 20 includes a chamber 21, a heater 22, a stage 23, a second solvent supply section 24, and a second solvent recovery section 25.

The chamber 21 forms a processing space where the supercritical drying processing to the wafer W by the supercritical drying processing unit 20 is performed. The processing space is, for example, configured so as to be capable of storing the wafer W having a diameter of 300 mm. After a second solvent used as the supercritical fluid is supplied to the chamber 21 in a liquid state, the second solvent is subjected to thermal processing and a phase thereof is changed to a supercritical state. Alternatively, a second solvent, whose phase has been previously changed to the supercritical state, may be directly supplied to the chamber 21. Further, a gaseous second solvent, which has been previously heated to a critical temperature or higher, may be supplied to the chamber 21 and a phase thereof is changed to the supercritical state by pressurizing. The chamber 21 is, for example, configured as a pressure resistant container formed of a stainless steel or the like.

The heater 22 raises a temperature of the processing space within the chamber 21. When the processing space is heated by the heater 22, a temperature and a pressure of the second solvent supplied to the surface of the wafer W are raised, and the phase of the second solvent is changed to the supercritical state. As illustrated in FIG. 2, the heater 22 may be embedded on a side surface of the chamber 21, may be embedded on an upper surface or a lower surface of the chamber 21, or may be provided inside or outside the chamber 21. The heater 22 is, for example, formed of a heating resistor. By controlling ON/OFF of the heater 22 by a control section (not illustrated), the temperature of the processing space can be adjusted.

The stage 23 is provided inside the chamber 21 and holds the wafer W introduced into the processing space. The stage 23 is, for example, configured as a disk-shaped holding member formed of a stainless steel or the like.

The second solvent supply section 24 includes a storage 241, which stores the second solvent, and a liquid feeding means for feeding the second solvent stored in the storage 241. A pressure resistant pump can be used as the liquid feeding means. The second solvent supply section 24 is connected to the chamber 21 via a solvent supply path 26, and the second solvent fed by the liquid feeding means is supplied to the chamber 21 via the solvent supply path 26. A valve 27, which opens and closes the solvent supply path 26, is provided on the solvent supply path 26.

The second solvent recovery section 25 includes a storage 251, which stores the second solvent recovered after the completion of the supercritical drying processing. The second solvent recovery section 25 is connected to the chamber 21 via a solvent discharge path 28, and the second solvent used for the supercritical drying processing is recovered by the second solvent recovery section 25 via the solvent discharge path 28. A valve 29, which opens and closes the solvent discharge path 28, is provided on the solvent discharge path 28.

A cooling section, which cools the second solvent, may be provided on the second solvent recovery section 25 or the solvent discharge path 28. With this configuration, the second solvent, which has been discharged from the inside of the chamber 21 in the supercritical state or as a gas, can be recovered in a liquid state. Further, a path for the second solvent may be provided between the second solvent supply section 24 and the second solvent recovery section 25, and the second solvent may be subjected to a predetermined regeneration processing in the second solvent recovery section 25. With this configuration, the second solvent recovered by the second solvent recovery section 25 is regenerated, and the regenerated second solvent can be supplied again from the second solvent supply section 24. Accordingly, the second solvent can be recycled.

It should be noted that the substrate processing apparatus may include conveying means, which conveys the wafer W into liquid processing chamber 11 of the liquid processing unit 10, and conveying means, which conveys the wafer W subjected to the liquid processing into the chamber 21 of the supercritical drying processing unit 20.

### (Intermediate Solvent, First Solvent, and Second Solvent)

Next, the intermediate solvent, the first solvent, and the second solvent used in the substrate processing method according to the present embodiment will be described. In the substrate processing method according to the present embodiment, the intermediate solvent, the first solvent, and the second solvent are used in that order. More specifically, after cleaning with the cleaning liquid, the wafer W is rinsed with in the order of the ultrapure water, the intermediate solvent, and the first solvent, and is subjected to the supercritical drying processing in a state in which the first solvent is filled up on the surface. In the supercritical drying processing, the second solvent is utilized as the supercritical fluid. In this substrate processing method, the first solvent is selected based on the second solvent utilized as the supercritical fluid, and the intermediate solvent is selected based on the first solvent. Consequently, description will be given below in the order of the second solvent, the first solvent, and the intermediate solvent.

The second solvent is, for example, a fluorine-containing organic solvent. More specifically, the second solvent is a fluorine-containing organic solvent, which becomes a supercritical fluid at a relatively low temperature and has solubility in the first solvent It is preferable that a critical temperature of the second solvent be lower than a critical temperature of the first solvent. By performing the supercritical drying processing with such a fluorine-containing organic solvent, the liquid attached to the surface of the wafer W is removed and the surface of the wafer W can be dried without causing a pattern collapse.

Generally, the fluorine-containing organic solvent is decomposed under a high temperature and high pressure atmosphere in the supercritical state, and is capable of generating fluorine atoms. The fluorine atoms can damage the wafer W by etching the surface of the wafer W or entering the inside of the wafer W. Accordingly, even in a case where the second solvent is processed, for example, at a high temperature and high pressure higher than or equal to a critical point, it is preferable that the second solvent he a fluorine-containing organic solvent, which has small heat decomposability and whose content of the fluorine atoms satisfies 100 wt. ppm or less. By using such a fluorine-containing organic solvent as the second solvent, damage to the wafer W by the fluorine atoms can be suppressed.

From the above-described viewpoints, for example, PFC (perfluoro carbon) is used as the second solvent. The PFC is a fluorine-containing organic solvent in which all hydrogens contained in hydrocarbon are substituted with fluorine. As the preferable PFC, Fluorinert (registered trademark) FC-72 (simply referred to as “FC-72” hereinafter) manufactured by Sumitomo 3M Limited can be given. A boiling point of the FC-72 is about 56° C., and a critical temperature thereof is about 177° C. It should be noted that the second solvent can be selected arbitrarily from among the fluorine-containing organic solvents and is not limited to the PFC.

The first solvent is a solvent which prevents drying of the surface of the wafer W, before the second solvent introduced into the chamber 21 is turned into a supercritical state in the chamber 21 and on the surface of the wafer W. Since the wafer W is introduced into the chamber 21 in the state in which the first solvent is filled up on the surface, and is subjected to the supercritical drying processing, it is necessary for the first solvent to have solubility in the second solvent. As such a first solvent, for example, the fluorine-containing organic solvent is used in the same way as the second solvent. By using the fluorine-containing organic solvent as the first solvent, introduction of moisture into the wafer W can be suppressed. Further, from the point of flame retardation as well, the fluorine-containing organic solvent is suitable as the solvent for preventing drying.

Moreover, it is preferable that the first solvent is a fluorine-containing organic solvent having a sufficiently high boiling point, e.g., the boiling point of 100° C. or higher. In order to change the phase of the second solvent to the supercritical state, a temperature of the chamber 21 is raised to the critical temperature of the second solvent or higher. At this time, it is necessary to suppress complete vaporization of the first solvent, which has been filled up on the surface of the wafer W, from the surface of the wafer W before the second solvent is substituted with the supercritical fluid. This is because if the first solvent filled up on the substrate surface completely vaporizes before the second solvent is substituted with the supercritical fluid, a pattern collapse can be generated. In the case where the boiling point of the first solvent is sufficiently high, a risk of drying the surface of the wafer W filled up with the first solvent can be reduced before the phase of the second solvent is changed to the supercritical state.

On the other hand, it is preferable that the boiling point of the first solvent be at a temperature lower than or equal to the critical temperature of the second solvent. This is because in the chamber 21, when the first solvent filled up on the surface of the wafer W is substituted with the second solvent, and then, the second solvent is vaporized by reducing a pressure in the chamber 21, reattachment of the first solvent to the surface of the wafer W is suppressed. In a case where the boiling point of the first solvent is higher than the critical temperature of the second solvent, when the second solvent is vaporized and discharged from the chamber 21, the first solvent can be reattached to the surface of the wafer W in a liquid state. The reattached first solvent causes a particle defect or a pattern collapse of a fine pattern. In contrast, in the case where the boiling point of the first solvent is at the temperature lower than or equal to the critical temperature of the second solvent, the phase of the second solvent is changed to gas by the pressure reduction of the chamber 21, and the phase of the first solvent is also changed to gas. Accordingly, reattachment of the liquid of the first solvent to the surface of the wafer W can be suppressed.

From the above-described viewpoints, it is preferable that the boiling point of the first solvent be sufficiently high within the range of the critical temperature of the second solvent or lower and, for example, it is preferable that the boiling point thereof be higher than the boiling point of the second solvent and lower than the critical temperature of the second solvent. As such first solvent, for example, a PFC having a sufficiently high boiling point is used. In a case where the second solvent is FC-72, Fluorinert (registered trademark) FC-43 (simply referred to as “FC-43” hereinafter) manufactured by Sumitomo 3M Limited can be used for the first solvent. A boiling point of the FC-43 is about 174° C., and is sufficiently high as compared to the boiling point of the FC-72 serving as the second solvent of about 56° C. Further, a critical temperature of the FC-43 is about 294° C., and is higher than the critical temperature of the FC-72 of about 177° C. In this way, in the case where the boiling point of the first solvent is sufficiently high within the range of the critical temperature of the second solvent or lower, the first solvent does not completely volatilize until the phase of the second solvent is changed to the supercritical state. Accordingly, drying of the surface of the wafer W can be suppressed. Moreover, since a vapor pressure of the first solvent is increased at the time when the phase of the second solvent is changed to the supercritical state, the first solvent exhibits high solubility in the supercritical fluid. It should be noted that the first solvent is not limited to the PFC, and can be selected arbitrarily from among the fluorine-containing organic solvents having solubility in the second solvent.

The intermediate solvent is a solvent for substituting the ultrapure water attached to the surface of the wafer W with the first solvent. Accordingly, it is necessary for the intermediate solvent to have solubility not only in the ultrapure water but also in the first solvent. Since a general fluorine-containing organic solvent has little or no solubility in the ultrapure water, it is difficult to directly substitute the ultrapure water attached to the surface of the wafer W with the first solvent. Accordingly, a solvent having solubility in both the ultrapure water and the first solvent is used as the intermediate solvent.

From the above-described viewpoints, for example, fluoroalcohol is used as the intermediate solvent. The fluoroalcohol not only has solubility in the ultrapure water and the fluorine containing organic solvent, but also has no or low combustibility. Accordingly, explosion-proof equipment is not needed, and a structure of the substrate processing apparatus can be simplified. The fluoroalcohol contains fluorinated alcohol having 1 to 6 carbon atoms. Particularly, HFIP (Hexa Fluoro Isopropyl Alcohol: 1,1,1,3,3,3-hexa fluoro-2-propanol) can be given as the preferable fluoroalcohol.

The HFIP has solubility in the ultrapure water, and also has solubility in the fluorine-containing organic solvent (e.g., FC-43). Further, from the point of flame retardation as well, the HFIP is suitable as the intermediate solvent. It should be noted that the intermediate solvent can be selected arbitrarily from among the solvents having solubility in the ultrapure water and the fluorine-containing organic solvent (the first solvent) and is not limited to the fluoroalcohol.

### (Substrate Processing Method)

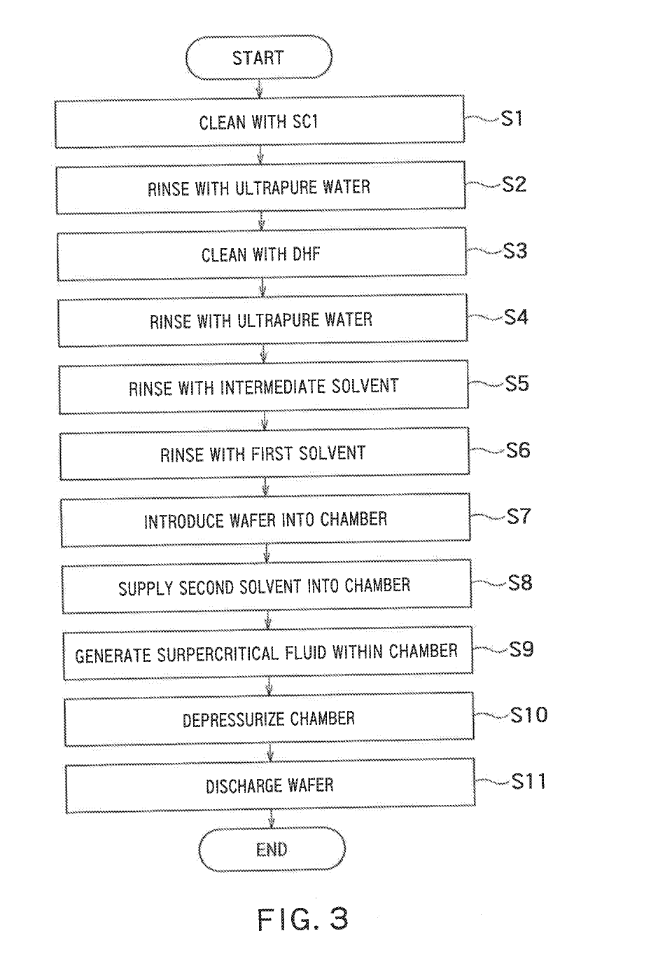

A substrate processing method according to the present embodiment will be described below with reference to FIG. 3, FIG. 3 is a process flow chart illustrating the substrate processing method according to the present embodiment.

First, the wafer W is conveyed into the liquid processing unit 10. The wafer holding section 12 holds the conveyed wafer W in the substantially horizontal state. Next, a cleaning liquid, such as SC1, is supplied from the cleaning liquid supply section 13, and cleaning of the wafer W is performed (step S1). With this configuration, particles and organic pollutants attached to the surface of the wafer W are removed.

Next, the ultrapure water is supplied from the ultrapure water supply section 14, and the surface of the wafer W is rinsed with the ultrapure water (step S2). With this configuration, residues and the cleaning liquid, such as SC1, attached to the surface of the wafer W are removed. Further, the cleaning liquid, such as DHF, is supplied from the cleaning liquid supply section 13, and the surface of the wafer W is cleaned (step S3). With this configuration, a natural oxide film formed on the surface of the wafer W is removed. Then, the ultrapure water is again supplied from the ultrapure water supply section 14, and the surface of the wafer W is rinsed with the ultrapure water (step S4). With this configuration, the residues and the cleaning liquid, such as DHF, attached to the surface of the wafer W are removed. The above-described cleaning processes may be performed using other cleaning liquids, and any type or number of the cleaning liquids may be used.

Next, the intermediate solvent is supplied from the intermediate solvent supply section 16, and the surface of the wafer W is rinsed with the intermediate solvent (step S5). Since the intermediate solvent has solubility in the ultrapure water, the ultrapure water attached to the surface of the wafer W is substituted with the intermediate solvent. As described above, the intermediate solvent is, for example, fluoroalcohol.

Further, the first solvent is supplied from the first solvent supply section 15, and the surface of the wafer W is rinsed with the first solvent (step S6). Since the intermediate solvent has solubility in the first solvent, the intermediate solvent attached to the surface of the wafer W is substituted with the first solvent. As described above, the first solvent is, for example, a fluorine-containing organic solvent.

Due to the above-described liquid processing, the first solvent is filled up on the surface of the wafer W. The liquid-processed wafer W is introduced into the chamber 21 of the supercritical drying processing unit 20 (step S7). It is preferable that the substrate processing apparatus include conveying means, which conveys the wafer W from the liquid processing unit 10 to the supercritical drying processing unit 20. Here, in a case where the first solvent is a fluorine-containing organic solvent having a high boiling point, evaporation of the first solvent during the conveyance of the wafer W and drying of the surface of the wafer W can be suppressed.

When the wafer W is introduced into the processing space within the chamber 21, the wafer W is held by the stage 23. Next, the second solvent is supplied in the liquid state from the second solvent supply section 24 into the chamber 21 via the solvent supply path 26 (step S8).

It should be noted that the supercritical drying processing unit 20 may previously raise the temperature of the chamber 21 before the wafer W is introduced. If the temperature is raised in advance, the time required for the supercritical drying processing can be shortened. Moreover, the supercritical drying processing unit 20 may previously fill inside housings of the supercritical drying processing unit 20 including the chamber 21 with inert gas, such as nitrogen gas or rare gas, before the wafer W is introduced. With this configuration, oxygen and moisture are discharged from the inside of the supercritical drying processing unit 20, and thermal decomposition of the second solvent can be suppressed.

When a predetermined amount of the second solvent is supplied into the chamber 21, the valves 27, 29 are closed, and an inside of the chamber 21 is sealed. Then, the temperature of the processing space and the wafer W within the chamber 21 is raised by the heater 22 so as to be higher than the critical point of the second solvent. For example, when the second solvent is FC-72, the temperature within the chamber 21 is raised to be about 200° C. With this configuration, the second solvent expands by heating inside the sealed chamber 21. Due to the expansion of the second solvent, the internal pressure of the chamber 21 is raised, and the phase of the second solvent is changed to the supercritical state. In other words, the supercritical fluid is generated within the chamber 21 by the second solvent (step S9). At this time, the first solvent is selected in such a manner that the first solvent attached to the surface of the wafer W does not completely volatilize before the supercritical fluid is generated at high temperature and high pressure.

It should be noted that the second solvent may be supplied into the chamber 21 in the supercritical state after the wafer W is introduced into the processing space within the chamber 21. In this case, the second solvent is supplied in a state in which the valve 29 is closed, and after the predetermined amount of second solvent is supplied into the chamber 21, the valve 27 is closed. Further, the second solvent in the gas state, which has been heated to a temperature higher than or equal to the critical temperature, may be supplied into the chamber 21 after the wafer W is introduced into the processing space within the chamber 21. In this case, the second solvent in the gas state is supplied by the pump in the state in which the valve 29 is closed, and after the predetermined amount of second solvent is supplied into the chamber 21, the valve 27 is closed. At this time, the second solvent is supplied until the pressure within the chamber 21 becomes a critical pressure of the second solvent or higher.

After the phase of the second solvent is changed to the supercritical state and the supercritical fluid is generated, the first solvent attached to the surface of the wafer W is extracted by the supercritical fluid, and the first solvent on the surface of the wafer W is substituted with the supercritical fluid. Then, after a predetermined time has passed, the valve 29 is opened, the Inside of the chamber 21 is immediately depressurized, and the phase of the supercritical fluid is changed to gas (step S10). Further, since the boiling point of the first solvent is lower than or equal to the critical temperature of the second solvent, the phase of the first solvent is changed to gas by such depressurization. Then, the first solvent and the second solvent whose phases have been changed to gas are discharged from the chamber 21, and recovered by the solvent recovery section 25 via the solvent discharge path 28. Accordingly, reattachment of the first solvent to the surface of the wafer W is suppressed, and a particle defect or a pattern collapse of a fine pattern can be prevented.

An interface between the supercritical state and the gas phase does not exist, and a phase change from the supercritical state to the gas is performed instantaneously. Therefore, the surface of the wafer W is dried instantaneously and evenly due to the vaporization of the second solvent. Accordingly, the surface of the wafer W can be dried without generating a pattern collapse affected by surface tension. Moreover, even in a case where the second solvent is processed at the high temperature and high pressure higher than or equal to the critical point, by using the fluorine-containing organic solvent, which has small heat decomposability and whose content of the fluorine atoms satisfies 100 wt. ppm or less, the fluorine atoms are hardly emitted from the second solvent accompanied by the supercritical drying processing. As a result, the wafer W can be dried while suppressing damage of the wafer W by the fluorine atoms.

After the internal pressure of the chamber 21 becomes approximately equal to atmospheric pressure, the wafer W is brought out from the chamber 21 (step S11). The substrate processing apparatus may include conveying means for bringing out the wafer W from the chamber 21.

As described above, according to the present embodiment, since the liquid (the first solvent) on the surface of the wafer W can be removed by using the supercritical fluid (the second solvent), the surface of the wafer W can be dried while suppressing occurrence of the pattern collapse. Further, since the supercritical drying processing is performed in the state in which the first solvent having a sufficiently high boiling point is filled up on the surface of the wafer W, drying of the surface of the wafer W can be suppressed. Moreover, by using the first solvent whose boiling point is lower than or equal to the critical temperature of the second solvent, the first solvent is substituted with the supercritical fluid at the temperature higher than the boiling point of the first solvent, and then, the phase of the supercritical fluid is changed to the gas. When the pressure is reduced from the high pressure condition to the atmospheric pressure for this phase change, the phase of the first solvent extracted by and substituted with the supercritical fluid is changed to gas without liquefying. Consequently, the first solvent is not reattached to the surface of the wafer W, and a particle defect or the pattern collapse of a fine pattern can be prevented.

Furthermore, by using the fluoroalcohol as the intermediate solvent, the ultrapure water attached to the surface of the wafer W can be easily substituted with the fluorine-containing organic solvent (the first solvent). With this configuration, the process until which the ultrapure water attached to the surface of the wafer W is substituted with the first solvent can be simplified, and the cost for liquid processing can be reduced. Further, by using the fluoroalcohol as the intermediate solvent, explosion-proof equipment is not needed, and equipment for the substrate processing apparatus can be simplified.

It should be noted that in the present embodiment, the substrate processing apparatus may be configured by integrating the liquid processing unit 10 and the supercritical drying processing unit 20, or the substrate processing apparatus may be configured by combining respectively independent devices.

### Second Embodiment

In the substrate processing method according to the first embodiment, when the ultrapure water is substituted with the first solvent, the intermediate solvent is used. However, a structure without using an intermediate solvent is also possible. In other words, in a substrate processing method according to the present embodiment, ultrapure water is directly substituted with a first solvent.

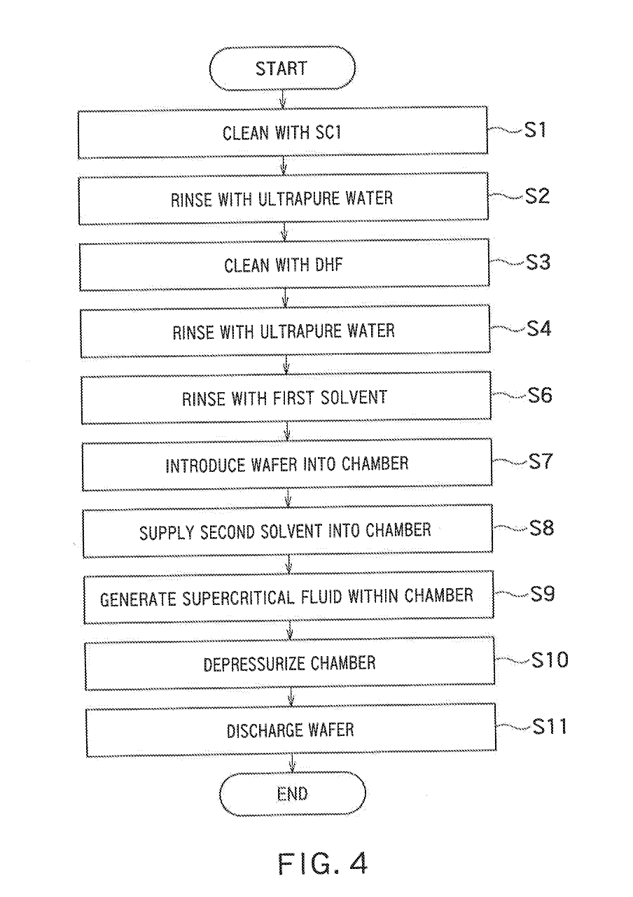

Here, FIG. 4 is a process flow chart illustrating an example of the substrate processing method according to a second embodiment. In FIG. 4, processes which are common to those in FIG. 3 are denoted by the same step numbers, and differences will be mainly described hereinafter.

In FIG. 4, the process of the step S5 in FIG. 3 is omitted, The first solvent used in a step S6 in FIG. 4 is, for example, fluoroalcohol which has solubility in the ultrapure water and has solubility in a second solvent (fluorine-containing organic solvent, such as FC-72) utilized as a supercritical fluid. By using such a first solvent, the ultrapure water and the first solvent can be directly substituted. Then, a wafer W is introduced into a chamber 21 in a state in which the first solvent is filled up (step S7), and supercritical drying processing similar to that in the first embodiment is performed (steps S8 to S11).

In a case in which the second solvent is FC-72, HFIP can be used as the first solvent. The HFIP has solubility in the ultrapure water and the FC-72. Further, a boiling point of the HFIP is about 59° C., and a critical temperature thereof is about 182.9° C. In other words, the boiling point of the HFIP is higher than the boiling point (about 56° C.) of the FC-72 and is lower than the critical temperature (about 177° C.) of the FC-72.

According to the present embodiment, the liquid processing process of the wafer W can be more simplified than the first embodiment, and the number of solvents used in the liquid processing can be reduced. Therefore, the cost for liquid processing can be further reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A substrate processing method, comprising:
supplying water to a surface of a substrate;
supplying a HFIP (1,1,1,3,3,3-hexa fluoro-2-propanol)-containing solvent to the surface of the substrate, to which the water has been attached;
supplying a first solvent, which has solubility in the HFIP-containing solvent, contains PFC (perfluoro carbon), and has a boiling point of 100° C. or higher, to the surface of the substrate, to which the HFIP-containing solvent has been attached;
introducing the substrate, to which the first solvent has been attached, into a chamber, substituting the first solvent on the surface of the substrate with a supercritical fluid, and then, changing the supercritical fluid in to gas by reducing a pressure within the chamber; and
bringing out the substrate from the chamber.

2. The method according to claim 1, wherein the supercritical fluid is a fluorine-containing solvent.

3. The method according to claim 1, wherein the boiling point of the first solvent is lower than a critical temperature of the supercritical fluid.

4. The method according to claim 1, wherein the boiling point of the first solvent is higher than a boiling point of the supercritical fluid.

5. The method according to claim 1, further comprising:
after introducing the substrate, to which the first solvent has been attached, into the chamber,
supplying a second solvent into the chamber; and
changing the second solvent to a supercritical state, and then, generating the supercritical fluid.

6. The method according to claim 5, wherein the second solvent is a PFC (perfluoro carbon)-containing solvent.

7. A substrate processing apparatus, comprising:
a water supply section which supplies water to a surface of a substrate;
a HFIP (1,1,1,3,3,3-hexa fluoro-2-propanol)-containing solvent supply section which supplies a HFIP -containing solvent to the surface of the substrate, to which the water has been attached;
a first solvent supply section which supplies a first solvent, which has solubility in the HFIP-containing solvent, contains PFC (perfluoro carbon), and has a boiling point of 100° C. or higher, to the surface of the substrate, to which the HFIP-containing solvent has been attached; and
a supercritical drying processing unit which introduces the substrate, to which the first solvent has been attached, into a chamber, substitutes the first solvent on the surface of the substrate with a supercritical fluid, and then, changes the supercritical fluid into gas by reducing a pressure within the chamber.

8. The apparatus according to claim 7, wherein the supercritical fluid is a fluorine-containing solvent.

9. The apparatus according to claim 7, wherein the boiling point of the first solvent is lower than a critical temperature of the supercritical fluid.

10. The apparatus according to claim 7, wherein the boiling point of the first solvent is higher than a boiling point of the supercritical fluid.

11. The apparatus according to claim 7, further comprising a second solvent supply section which supplies a second solvent into the chamber;
wherein the supercritical drying processing unit changes the second solvent to a supercritical state, and then, generates the supercritical fluid.

12. The apparatus according to claim 11, wherein the second solvent is a PFC-containing solvent.

13. A substrate processing method, comprising:
supplying water to a surface of a substrate;
supplying a fluoroalcohol-containing solvent, which has flame retardance, to the surface of the substrate, to which the water has been attached;
supplying a first solvent, which has solubility in the fluoroalcohol-containing solvent, contains PFC (perfluoro carbon), and has a boiling point of 100° C. or higher, to the surface of the substrate, to which the fluoroalcohol-containing solvent has been attached;
introducing the substrate, to which the first solvent has been attached, into a chamber, substituting the first solvent on the surface of the substrate with a supercritical fluid, and then, changing the supercritical fluid into gas by reducing a pressure within the chamber; and
bringing out the substrate from the chamber.

14. The method according to claim 13, wherein the fluoroalcohol is HFIP (1,1,1,3,3,3-hexa fluoro-2-propanol).

15. The method according to claim 13, wherein the supercritical fluid is a fluorine-containing solvent.

16. The method according to claim 13, wherein the boiling point of the first solvent is lower than a critical temperature of the supercritical fluid.

17. The method according to claim 13, wherein the boiling point of the first solvent is higher than a boiling point of the supercritical fluid.

18. The method according to claim 13, further comprising:
after introducing the substrate, to which the first solvent has been attached, into the chamber,
supplying a second solvent into the chamber; and
changing the second solvent to a supercritical state, and then, generating the supercritical fluid.

19. The method according to claim 18, wherein the second solvent is a PFC-containing solvent.

20. A substrate processing apparatus, comprising:
a water supply section which supplies water to a surface of a substrate;
a fluoroalcohol-containing solvent supply section which supplies a fluoroalcohol-containing solvent, which has flame retardance, to the surface of the substrate, to which the water has been attached;
a first solvent supply section which supplies a first solvent, which has solubility in the fluoroalcohol-containing solvent, contains PFC (perfluoro carbon), and has a boiling point of 100° C. or higher, to the surface of the substrate, to which the fluoroalcohol-containing solvent has been attached; and
a supercritical drying processing unit which introduces the substrate, to which the first solvent has been attached, into a chamber, substitutes the first solvent on the surface of the substrate with a supercritical fluid, and then, changes the supercritical fluid into gas by reducing a pressure within the chamber.

21. The apparatus according to claim 20, wherein the fluoroalcohol is HFIP (1,1,1,3,3,3-hexa fluoro-2-propanol).

22. The apparatus according to claim 20, wherein the supercritical fluid is a fluorine-containing solvent.

23. The apparatus according to claim 20, wherein the boiling point of the first solvent is lower than a critical temperature of the supercritical fluid.

24. The apparatus according to claim 20, wherein the boiling point of the first solvent is higher than a boiling point of the supercritical fluid.

25. The apparatus according to claim 20, further comprising a second solvent supply section which supplies a second solvent into the chamber;
wherein the supercritical drying processing unit changes the second solvent to a supercritical state, and then, generates the supercritical fluid.

26. The apparatus according to claim 25, wherein the second solvent is a PFC-containing solvent.
